(19) United States
(12) Patent Application Publication
(10) Pub. No.: US 2024/0093411 A1
(43) Pub. Date: Mar. 21, 2024

(54) MODIFIED CROSS-SECTION FIBER

(71) Applicant: Murata Manufacturing Co., Ltd., Nagaokakyo-shi, Kyoto-fu (JP)

(72) Inventors: Tetsuya YAMANAGA, Nagaokakyo-shi (JP); Kenichi MORI, Nagaokakyo-shi (JP); Masayuki TSUJI, Nagaokakyo-shi (JP); Masayoshi TAKAGI, Nagaokakyo-shi (JP); Ryosuke EBINA, Osaka (JP)

(21) Appl. No.: 18/513,836

(22) Filed: Nov. 20, 2023

Related U.S. Application Data
(63) Continuation of application No. PCT/JP2022/017019, filed on Mar. 29, 2022.

(30) Foreign Application Priority Data
May 25, 2021 (JP) 2021-087784

(51) Int. Cl. D02G 3/44; H10N 30/00

(52) U.S. Cl. CPC D02G 3/441; H10N 30/1061; D10B 2331/04

(57) ABSTRACT

A fiber with which a further enhanced electric field intensity is obtained when a compressive force is applied across the longitudinal axis of the fiber. The fiber is composed of a potential generating filament having at least one interior angle of less than 120° in a contour shape in a sectional view in a direction perpendicular to a longitudinal axis of the fiber.

### CROSS REFERENCE TO RELATED APPLICATIONS

The present application is a continuation of International application No. PCT/JP2022/017019, filed Mar. 29, 2022, which claims priority to Japanese Patent Application No. 2021-087784, filed May 25, 2021, the entire contents of each of which are incorporated herein by reference.

### TECHNICAL FIELD

The present disclosure relates to a modified cross-section fiber having a fiber cross-section that is not circular. More specifically, the present disclosure relates to a modified cross-section fiber composed of a potential-generating filament.

### BACKGROUND ART

For example, JP 6428979 B and JP 6508371 B disclose piezoelectric yarns containing fibers capable of generating charges by external energy to form an electric field.
Patent Document 1: JP 6428979 B
Patent Document 2: JP 6508371 B

### SUMMARY

The inventors of the present application have noticed that there are problems to be overcome with conventional piezoelectric yarns, and have found the need to take measures therefor. Specifically, the inventors of the present application found that there are the following problems.

For example, the piezoelectric yarns disclosed in JP 6428979 B and JP 6508371 B can generate charges by external energy (for example, pulling in the axial direction of a yarn). In addition, an antibacterial effect of inhibiting proliferation of bacteria and fungi by an electric field that can be formed through generation of such charges is expected. Such piezoelectric yarns are expected to have an effect of inhibiting generation of bacteria in clothing, particularly underwear and socks, and an effect of killing bacteria.

For example, when application to socks was studied, it was found that pressure concentrates to the periphery of the metatarsal and calcaneus of the sole during walking, for example, as shown in FIG. 15 (contour part A). It has been found that when a pressure of about 1.3 kg/cm 2 is applied to such a part A (=12.7 N/cm 2), at most, a maximum pressure of 2.3 kg/cm 2 is applied to contour part B (=22.5 N/cm 2) (based on data produced by Consumer Product End-Use Research Institute Co., Ltd. by averaging the pressure applied to a sensor when a woman walked six steps with sneakers (https://www.shoukaken.co.jp/news/1766/)). In addition, a research by the inventors of the present application has revealed that a compressive force is applied to the sole from a direction of 0° to 90° at that time. Furthermore, the research by the inventors has also revealed that when a pressure of 22.5 N/cm² is applied to a plain woven fabric, which is one of typical fabrics, a load of about 3.5×10⁻⁴ N is applied per fiber, and when a pressure of 12.7 N/cm 2 is applied, about 2.0×10⁻⁴ N is applied per fiber. In addition, it is considered that the same load as described above is applied per fiber to a knitted fabric such as a knit or a nonwoven fabric.

Therefore, the inventors of the present application studied the generation of charges and potentials by piezoelectric yarns in a compressed portion or compressed region to which such a load is applied, and further improvement of the antibacterial effect through more effective formation of an electric field.

However, conventional piezoelectric yarns exhibit an antibacterial effect through forming an electric field by external energy, in particular, pulling in the axial direction of a yarn or fiber, and a research by the inventors of the present application has revealed that when a compressive force is applied across the longitudinal axis of a fiber from a direction of 0° to 90° with respect to the longitudinal axis of the fiber, in particular, from a direction of an angle of 45°, the resulting electric field intensity is insufficient.

The present disclosure has been devised in light of the above problems. That is, a main object of the present disclosure is to provide a fiber with which a further enhanced electric field intensity is obtained when a compressive force is applied across the longitudinal axis of the fiber.

The present inventors tried to solve the above-described problems by addressing in a new direction, instead of dealing as the extension of the conventional technologies. As a result, the inventors have reached a disclosure of a fiber with which the above-described main object is achieved.

In the present disclosure, it has been studied to change a cross section of a fiber to a modified cross section having at least one corner, such as a triangular or quadrangular cross section, instead of a general circular cross section so that a further enhanced electric field intensity can be obtained when a compressive force is applied from a direction oblique with respect to the longitudinal axis of the fiber. This is because the present inventors have considered that owing to the condition that the section of the fiber has at least one corner, when a compressive force is applied to the fiber from a direction oblique with respect to the fiber, the compressive force is concentrated to the corner, and as a result, a potential can be generated more efficiently to form an electric field.

As a result of intensive studies, the present inventors have found that the electric field intensity is remarkably enhanced by the presence of at least one interior angle having an angle measure of less than 120° in a contour shape in a sectional view in a direction perpendicular to the longitudinal axis of a fiber.

The present disclosure provides a modified cross-section fiber comprising a potential-generating filament, comprising at least one interior angle of less than 120° in a contour shape in a sectional view in a direction perpendicular to the longitudinal axis of the fiber.

The present disclosure provides a fiber that is to have a further enhanced electric field intensity when a compressive force is applied across the longitudinal axis of the fiber. It is noted that the effects described in the present specification are merely examples and are not limited, and additional effects may be provided.

### BRIEF DESCRIPTION OF THE DRAWINGS

FIG. 1 is a schematic view (side view) schematically illustrating a modified cross-section fiber of the present disclosure;

FIGS. 2A to 2C are schematic views each schematically illustrating an example of a cross section of a modified cross-section fiber;

FIGS. 3A to 3C are schematic views each schematically illustrating an example of a cross section and an interior angle of a modified cross-section fiber;

FIGS. 4A to 4D are schematic views each schematically illustrating another example of a cross section and an interior angle of a modified cross-section fiber;

FIG. 5 is a schematic view for schematically explaining an interior angle in a cross section of a modified cross-section fiber;

FIGS. 6A and 6B are schematic views each schematically illustrating the modified cross-section fiber of the present disclosure in Example 1;

FIGS. 7A and 7B are diagrams each showing the potential of the modified cross-section fiber of the present disclosure in Example 1;

FIG. 8 is a diagram showing the electric field of the modified cross-section fiber of the present disclosure in Example 1;

FIG. 9 is a graph showing electric field intensities of the fibers of Examples 1 to 3 and Comparative Examples 1 to 7;

FIGS. 10A and 10B are schematic views each schematically illustrating the modified cross-section fiber (hollow fiber) of the present disclosure in Example 4;

FIGS. 11A and 11B are diagrams each showing the potential of the modified cross-section fiber (hollow fiber) of the present disclosure in Example 4;

FIG. 12 is a diagram showing the electric field of the modified cross-section fiber (hollow fiber) of the present disclosure in Example 4;

FIG. 13 is a graph showing the electric field intensity of the modified cross-section fibers (triangular cross-section) of the present disclosure in Example 1 and Examples 4 to 6;

FIG. 14 is a graph showing the electric field intensities of the modified cross-section fibers (pentagonal cross-section) of the present disclosure in Example 3 and Examples 7 to 9; and

FIG. 15 is a diagram showing a foot pressure at the time of walking with a sneaker.

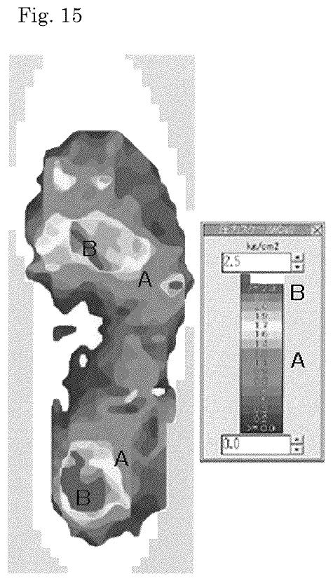

### DETAILED DESCRIPTION OF THE PREFERRED EMBODIMENTS

The present disclosure relates to modified cross-section fibers having a fiber cross-section that is not circular, and preferably to modified cross-section fibers having at least one corner. More specifically, the present disclosure relates to a modified cross-section fiber composed of a potential-generating filament.

In the present disclosure, the term “modified cross-section fiber” generally means that the contour of a cross-sectional shape of the fiber is not circular (including elliptical and ovoid shapes), in other words, is non-circular. Specifically, it means that the contour shape in a sectional view in a direction perpendicular to the longitudinal axis of the fiber is not circular (including elliptical and ovoid shapes), in other words, is non-circular, and at least a part of the contour shape of the fiber may have a corner or may be angular.

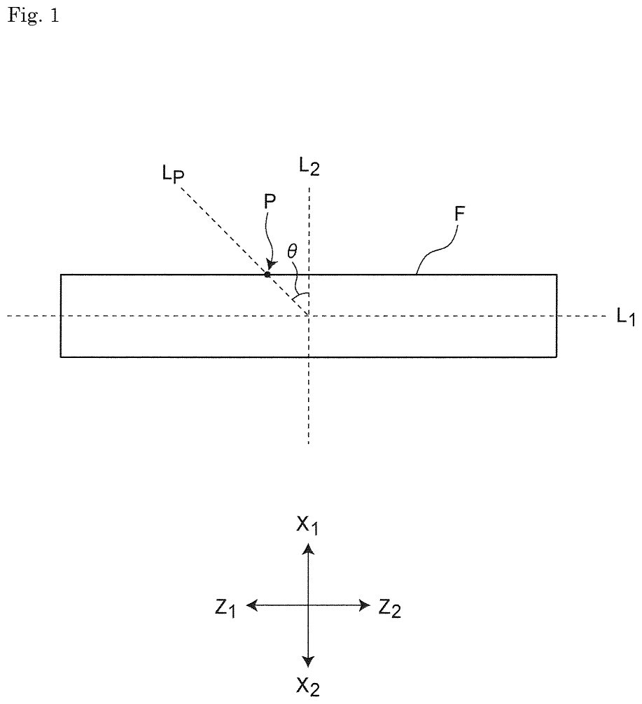

More specifically, the term “modified cross-section fiber” means that, as shown in FIG. 1 (side view) for example, in a fiber or filament (F) (hereinafter sometimes referred to as “fiber (F)”), a contour shape in a sectional view in a fiber perpendicular direction along a straight line L₂ extending in a direction perpendicular to the longitudinal axis of the fiber (F) indicated by a straight line L₁ is not circular (including elliptical and ovoid shapes), in other words, is non-circular.

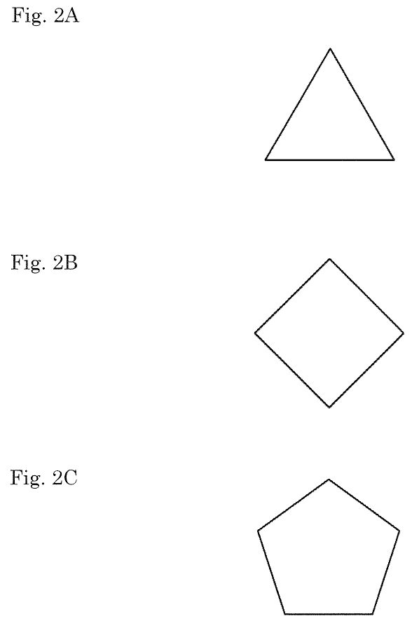

The contour shape in a sectional view in a direction perpendicular to the longitudinal axis of the fiber (F) may have a geometric shape. For example, as shown in FIGS. 2A to 2C, the contour shape in a sectional view in a direction perpendicular to the longitudinal axis of the fiber (F) may have a polygonal shape such as a triangle, a quadrangle, or a pentagon, or may have a star shape or the like. The contour shape of the fiber in a sectional view is not particularly limited as long as the contour shape has at least one corner. In other words, the modified cross-section fiber of the present disclosure is a fiber in which a contour shape in a sectional view in a direction perpendicular to the longitudinal axis of the fiber may have at least one corner. The position of the corner in the contour shape is not particularly limited.

Owing to the condition that the contour shape of the fiber in a sectional view has at least one corner, when a compressive force is applied from a direction oblique with respect to the longitudinal axis of the fiber, the force is concentrated to the corner and, as a result, a potential can be more efficiently generated to form an electric field.

The modified cross-section fiber of the present disclosure is a fiber composed of a “potential-generating filament” to be described in detail below, wherein a contour shape in a sectional view in a direction perpendicular to a longitudinal axis of the fiber has at least one interior angle having an angle measure of less than 120° (hereinafter, the modified cross-section fiber of the present disclosure may be referred to as a “fiber of the present disclosure”). Owing to the condition that the fiber of the present disclosure has at least one such interior angle or corner, when a compressive force is applied from an oblique direction of the fiber, a force is concentrated to such a portion and, as a result, a potential can be generated more efficiently to form an electric field.

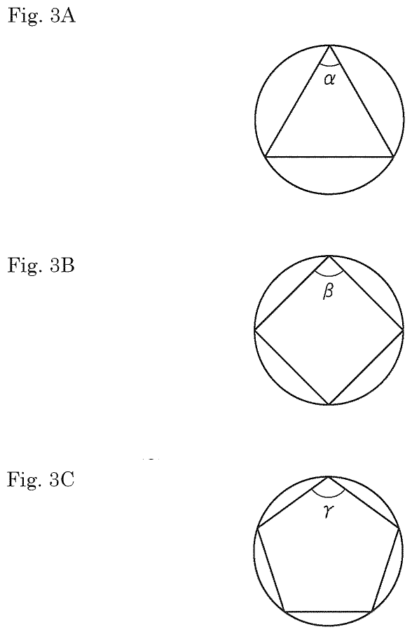

In order to more easily understand the fiber of the present disclosure, for example, an equilateral triangular cross-sectional shape as a typical triangular cross-sectional shape is illustrated in FIG. 3A, a square cross-sectional shape as a typical quadrangular cross-sectional shape is illustrated in FIG. 3B, and a regular pentagonal cross-sectional shape as a typical pentagonal cross-sectional shape is illustrated in FIG. 3C.

In the equilateral triangle shown in FIG. 3A, all the vertices are inscribed in a circle, and the angle measure of an interior angle α is 60°.

In the square shown in FIG. 3B, all the vertices are inscribed in a circle, and the angle measure of an interior angle β is 90°.

In the regular pentagon shown in FIG. 3C, all the vertices are inscribed in a circle, and the angle measure of an interior angle γ is 108°.

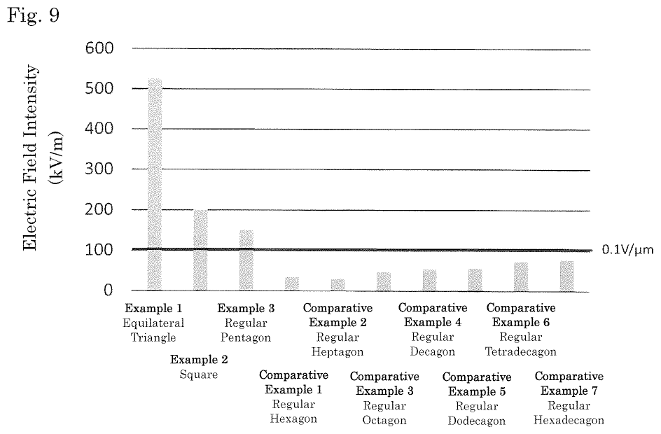

As described above, in the fiber of the present disclosure, a contour shape in a sectional view in a direction perpendicular to the longitudinal axis of the fiber has at least one interior angle having an angle measure of less than 120°, preferably 108° or less. Since the angle measure of the interior angle is less than 120°, when a compressive force is applied from an oblique direction of the fiber of the present disclosure, a force is applied to such an interior angle or corner in a concentrated manner, and as a result, the fiber can more efficiently generate a potential and form an electric field. As a result, an electric field intensity of 100 kV/m or more or 0.1 V/μm or more can be obtained. When the angle measure of the interior angle is 120° or more, for example, in the case of a regular hexagon, the value of the electric field intensity may significantly decrease to be less than 100 kV/m or 0.1 V/μm (see FIG. 9).

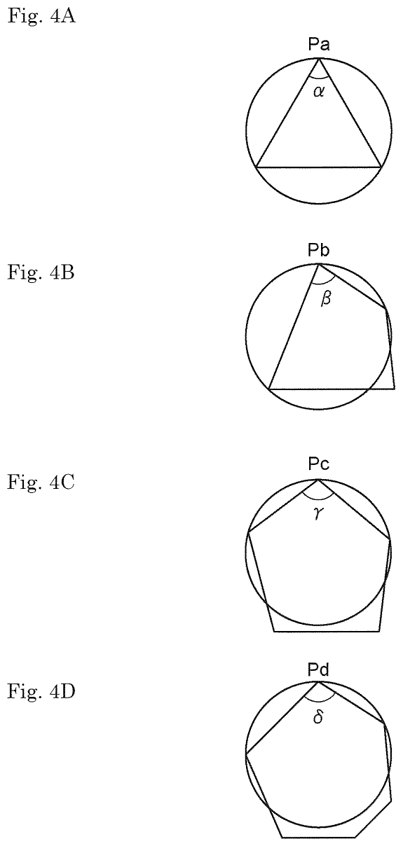

Regarding the interior angle, for example, in FIG. 4A, an equilateral triangle is shown as a contour shape in a sectional view in a direction perpendicular to the longitudinal axis of the fiber similarly to FIG. 3A, but the angle measure of the interior angle α of a vertex or corner Pa of the triangle shown in FIG. 4A may be less than 120°, and the triangle may have any shape.

For example, in FIG. 4B, a quadrangle is shown as an example of a contour shape in a sectional view in a direction perpendicular to the longitudinal axis of the fiber, but not all vertices or corners are required to exist on the circumference as in the square shown in FIG. 3B. Therefore, the angle measure of the interior angle R of the vertex or corner Pb of the quadrangle illustrated in FIG. 4B is just required to be less than 120°, and the quadrangle may have any shape.

For example, in FIG. 4C, a pentagon is shown as an example of a contour shape in a sectional view in a direction perpendicular to the longitudinal axis of the fiber, but not all vertices or corners are required to exist on the circumference as in the regular pentagon shown in FIG. 3C. Therefore, the angle measure of the interior angle γ of the vertex or corner Pc of the pentagon shown in FIG. 4C is just required to be less than 120°, and the pentagon may have any shape.

For example, in FIG. 4D, a hexagon is shown as an example of a contour shape in a sectional view in a direction perpendicular to the longitudinal axis of the fiber. The angle measure of the interior angle δ of the vertex or corner Pd of the hexagon shown in FIG. 4D is just required to be less than 120°, and may be a hexagon of any shape (however, regular hexagons having all interior angles of 120° are excluded).

As described above, in the fiber of the present disclosure, it is important that the fiber has at least one interior angle of less than 120° in a contour shape in a sectional view in a direction perpendicular to a longitudinal axis of the fiber. However, the contour shape in a sectional view in a direction perpendicular to the longitudinal axis of the fiber should not be interpreted as being limited to any of the above shapes.

In a preferred embodiment, the interior angle of a corner that can be included in the contour shape in a sectional view in a direction perpendicular to the longitudinal axis of the fiber may be defined as follows.

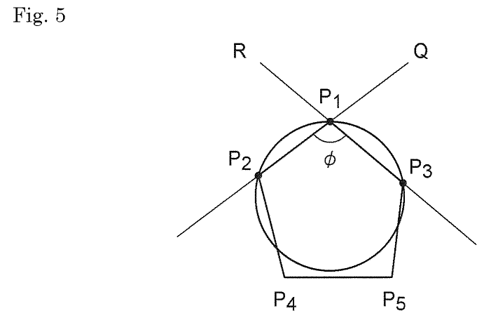

For example, as shown in FIG. 5, in the case of a pentagon, at least three adjacent or continuous vertices (P₁, P₂, P₃) among the five vertices are located on the circumference, and a corner that can be formed by a straight line Q connecting the middle vertex P₁ of the three vertices and one vertex P₂ adjacent thereto and a straight line R connecting the middle vertex P₁ and the other vertex P₃ adjacent thereto is defined as an “interior angle”, and the angle measure φ thereof is just required to be less than 120°. At this time, the remaining two vertexes (P₄, P₅) may be located outside the circle as illustrated, or may be located inside the circle. The definition of an interior angle is not limited to a polygon such as a pentagon, and can be applied to any geometric shape.

In the fiber of the present disclosure, when the contour shape in a sectional view in a direction perpendicular to the longitudinal axis of the fiber has a plurality of corners, the angle measures of the interior angles may be different from each other or may be the same.

In the fiber of the present disclosure, the angle measure of an interior angle is preferably 108° or less in the contour shape in a sectional view in a direction perpendicular to the longitudinal axis of the fiber. Owing to the condition that the fiber of the present disclosure has such an angle measure of an interior angle, when a compressive force is applied from an oblique direction of the fiber, the force is more concentrated to such a corner and, as a result, a potential can be more efficiently generated to form an electric field (see FIG. 9).

In this case, the angle measure of the interior angle is larger than 0°, and may be, for example, 100° or more.

In the fiber of the present disclosure, the angle measure of an interior angle is preferably 90° or less in the contour shape in a sectional view in a direction perpendicular to the longitudinal axis of the fiber. Owing to the condition that the fiber of the present disclosure has such an angle measure of an interior angle, when a compressive force is applied from an oblique direction of the fiber, the force is more concentrated to such a corner and, as a result, a potential can be more efficiently generated to form an electric field (see FIG. 9).

In this case, the angle measure of the interior angle is larger than 0°, and may be, for example, 80° or more.

In the fiber of the present disclosure, the angle measure of an interior angle is preferably 60° or less in the contour shape in a sectional view in a direction perpendicular to the longitudinal axis of the fiber. Owing to the condition that the fiber of the present disclosure has such an angle measure of an interior angle, when a compressive force is applied from an oblique direction of the fiber, the force is more concentrated to such a corner and, as a result, a potential can be more efficiently generated to form an electric field (see FIG. 9).

In this case, the angle measure of the interior angle is larger than 0°, and may be, for example, 50° or more.

In the fiber of the present disclosure, the angle measure of an interior angle is preferably 60° to 108° in the contour shape in a sectional view in a direction perpendicular to the longitudinal axis of the fiber. Owing to the condition that the fiber of the present disclosure has an interior angle having an angle measure in such a range, when a compressive force is applied from an oblique direction of the fiber, a force is further concentrated to such a corner and, as a result, a potential can be generated more efficiently to form an electric field (see FIG. 9).

In the fiber of the present disclosure, a potential can be generated by pressing the fiber in a direction crossing the longitudinal axis of the fiber. In the fiber of the present disclosure, the direction crossing the longitudinal axis of the fiber is not particularly limited.

For example, as illustrated in FIG. 1, the fiber (F) may have, for example, a longitudinal axis indicated by a straight line L₁ along the fiber body. In the fiber of the present disclosure, a potential can be generated by pressing (or simply pushing) the fiber in a direction crossing the longitudinal axis of the fiber or the straight line L₁.

In the fiber of the present disclosure, a potential can be generated by, for example, pressing the fiber (F) in a direction crossing the longitudinal axis of the fiber (F) or the straight line L₁ along the straight line Lp in an oblique direction shown in FIG. 1. The position where the fiber (F) is pressed at this time is indicated by reference sign P. The position indicated by the reference sign P may correspond to, for example, Pa to Pd in FIGS. 4A to 4D or P₁ in FIG. 5. In other words, a vertex or corner indicated by Pa to Pd in FIGS. 4A to 4D or P₁ in FIG. 5 may be located at the position indicated by reference sign P in FIG. 1.

The direction of the straight line Lₚ may be either a direction along the fiber in top view or a direction crossing the fiber. In other words, the direction of the straight line Lₚ as viewed from above is not particularly limited.

As described above, by pressing at least one corner that can be included in a contour shape in a sectional view in a direction perpendicular to the longitudinal axis of the fiber of the present disclosure or compressing the fiber at the position P, a potential can be generated in the fiber. For example, when the fiber (F) illustrated in FIG. 1 is applied with a compressive force from an oblique direction at such a corner or position P, a force is applied to the fiber at the corner or position P in a more concentrated manner and, as a result, a potential can be more efficiently generated in the fiber to form an electric field.

In the fiber of the present disclosure, a potential can be generated in the fiber by pressing a corner obliquely from a direction perpendicular to the longitudinal axis of the fiber or compressing a corner at the position P. For example, as illustrated in FIG. 1, a potential can be generated in the fiber (F) by pressing or compressing the fiber (F) with an inclination or a shift or an angle with respect to the straight line L₂ perpendicular to the longitudinal axis or the straight line L₁ of the fiber (F). More specifically, a potential can be generated in the fiber by pressing or compressing the fiber (F) at the position P along the straight line Lₚ in the oblique direction shown in FIG. 1. In the illustrated embodiment, the straight line Lₚ may be inclined at an angle measure θ with respect to the straight line L₂. By thus pressing or compressing the fiber (F) along the straight line Lₚ extending in a direction oblique to the longitudinal axis of the fiber (F), a potential can be generated in the fiber. As described above, a potential can be more efficiently generated not only by pulling in the longitudinal axis direction of the fiber, but alternatively by applying a force from an oblique direction, especially by compressing the fiber.

In the fiber of the present disclosure, a potential can be generated in the fiber by pressing or compressing a corner obliquely within a range of 0° to 90° (preferably not including 0° and 90°) with respect to a direction perpendicular to the longitudinal axis of the fiber. More specifically, a potential can be more efficiently generated in the fiber by, as illustrated in FIG. 1, pressing or compressing a corner or position P of the fiber obliquely within a range of 0° to 90° (preferably not including 0° and 90°) with respect to a direction along the straight line L₂ that is perpendicular to the longitudinal axis of the fiber (F) or to the straight line L₁. In other words, a potential can be more efficiently generated in the fiber by pressing or compressing the corner or position P of the fiber (F) with the straight line Lₚ being inclined with an angle measure θ at an intersection between the straight line Lₚ and the straight line L₂ illustrated in FIG. 1 being 0° to 90° (however, it is preferable that 0 is not 0° or 90°). If a potential can be generated in the fiber (F) by pressing or compressing the fiber (F) from an oblique direction at such an angle measure θ, a potential can be more efficiently generated in the fiber (F) not only by applying a tension in the longitudinal axis direction of the fiber (F) (or the direction along the straight line L₁) or pressing in the perpendicular direction (or the direction along the straight line L₂), but alternatively by applying a compressive force from various angles.

In the fiber of the present disclosure, a potential can be generated in the fiber by pressing or compressing a corner of the fiber obliquely at 45° with respect to a direction perpendicular to the longitudinal axis of the fiber. More specifically, a potential can be more efficiently generated in the fiber (F) by pressing or compressing the corner or position P obliquely at 45° with respect to a direction along the straight line L₂ that is perpendicular to the longitudinal axis of the fiber (F) or to the straight line L₁ as illustrated in FIG. 1. In other words, a potential can be more efficiently generated in the fiber by pressing or compressing the corner or position P of the fiber along the straight line Lₚ with an angle measure θ at an intersection between the straight line Lₚ and the straight line L₂ illustrated in FIG. 1 being 45°. If a potential can be generated in the fiber (F) by pressing or compressing the fiber from an oblique direction at such an angle measure θ, a potential can be more efficiently generated in the fiber (F) not only by applying a tension in the longitudinal axis direction of the fiber (F) (or the direction along the straight line L₁) or pressing in the perpendicular direction (or the direction along the straight line L₂), but alternatively by applying a compressive force to the fiber from various angles.

The fiber of the present disclosure may be a “hollow fiber”. In other words, the fiber of the present disclosure may have a cavity therein. More specifically, the fiber may have a cavity having a circular or polygonal section along the longitudinal axis of the fiber. Owing to the condition that the fiber of the present disclosure is a hollow fiber, the fiber has flexibility and is easily applied with a compressive force from various angles, and a potential can be generated more efficiently.

The fiber of the present disclosure is composed of a “potential-generating filament”, and as described above, can exhibit an electric field intensity of “100 kV/m or more” or “0.1 V/μm or more” by having at least one interior angle having an angle measure of less than 120° in a contour shape in a sectional view in a direction perpendicular to the longitudinal axis of the fiber (see FIG. 9). The fiber of the present disclosure can exhibit a more improved antibacterial effect and the like because of having such an electric field intensity. Therefore, the fiber of the present disclosure can be used as an antibacterial fiber or an antibacterial yarn.

(Potential-Generating Filament)

In the present disclosure, a “potential-generating filament” means a fiber (or filament) capable of generating a charge and a potential and forming an electric field by an external energy, especially, a compressive force, more specifically a compressive force in a direction crossing the longitudinal axis of a fiber (hereinafter, the potential-generating filament may be called “potential-generating fiber”, “charge-generating fiber (or charge-generating filament)”, “electric field-forming fiber (or electric field-forming filament)”, or simply “fiber” or “filament”).

Examples of the “external energy” include force from outside (hereinafter, sometimes referred to as “external force”), specifically, a force which makes a fiber have deformation or strain, especially, a compressive force, and/or a force which is applied in the axial direction of a fiber, more specifically, a tension (e.g., a tension in the axial direction of a fiber) and/or a stress or strain force (a tensile stress or tensile strain applied to a fiber) and/or an external force such as force applied in the transverse direction of a fiber.

It is preferable that the fiber generates a potential due to a compressive force among external forces, especially a compressive force in a direction crossing the longitudinal axis of the fiber. For example, a compressive force in a direction transverse to the longitudinal axis of the fiber with an inclination in a range of 0° to 90° (preferably not including 0° and 90°) from a direction perpendicular to the longitudinal axis of the fiber is preferable, and a compressive force in a direction crossing the longitudinal axis of the fiber with an inclination of 45° from a direction perpendicular to the longitudinal axis of the fiber is more preferable.

The magnitude or load of an external force such as a compressive force is, for example, 1×10⁻⁴ N or more, and preferably 1.5×10⁻⁴ N to 3×10⁻⁴ N per fiber.

The fiber may be either a long fiber or a short fiber. The fiber may have a length (or dimension) of, for example, 0.01 mm or more, preferably 0.1 mm or more, more preferably 1 mm or more, even more preferably 10 mm or more, or 20 mm or more, or 30 mm or more. The length may be appropriately chosen according to a desired application. The upper limit value of the length is not particularly limited, and is, for example, 10,000 mm, 100 mm, 50 mm, or 15 mm.

The thickness, height, depth, or single fiber diameter of the fiber is not particularly limited, and may be the same (or constant) or may not be the same along the length of the fiber. The fiber may have a thickness, height, depth, or single fiber diameter of, for example, 0.001 μm (1 nm) to 1 mm, preferably 0.01 μm to 500 μm, more preferably 0.1 μm to 100 μm, and particularly 1 μm to 50 μm, such as 10 μm or 30 μm. These values may be the largest dimension of a fiber section.

The fiber preferably contains a material having a piezoelectric effect (polarization phenomenon due to external force) or piezoelectricity (the property of generating a voltage when a mechanical strain is applied or, conversely, generating a mechanical strain when a voltage is applied) (hereinafter, sometimes referred to as a “piezoelectric material” or a “piezoelectric substance”).

As the piezoelectric material, any material having a piezoelectric effect or piezoelectricity can be used without particular limitation, and may be an inorganic material such as piezoelectric ceramics or may be an organic material such as a polymer.

The piezoelectric material preferably comprises a “piezoelectric polymer”.

Examples of the piezoelectric polymer include a “piezoelectric polymer having pyroelectricity” and a “piezoelectric polymer having no pyroelectricity”.

“Piezoelectric polymer having pyroelectricity” generally means a piezoelectric material composed of a polymer material (polymeric material or resin material) that has pyroelectricity and is capable of generating charges on its surface upon, for example, application of temperature changes. Examples of such a piezoelectric polymer include polyvinylidene fluoride (PVDF). In particular, one capable of generating electric charges on the surface thereof by thermal energy from a human body is preferable.

“Piezoelectric polymer having no pyroelectricity” generally means a piezoelectric polymer (hereinafter, sometimes referred to as “polymeric piezoelectric substance”) composed of a polymer material (polymeric material or resin material) and excluding the “piezoelectric polymer having pyroelectricity” described above. Examples of such a piezoelectric polymer include polylactic acid (PLA).

As the polylactic acid (PLA), poly-L-lactic acid (PLLA), in which an L-form monomer is polymerized, (in other words, a polymer composed substantially only of repeating units derived from L-lactic acid monomers), poly-D-lactic acid (PDLA), in which a D-form monomer is polymerized, (in other words, a polymer composed substantially only of repeating units derived from D-lactic acid monomers), and mixtures thereof are known.

As the polylactic acid (PLA), a copolymer of L-lactic acid and/or D-lactic acid with a compound copolymerizable with the L-lactic acid and/or D-lactic acid may be used.

As the polylactic acid (PLA), a mixture of “polylactic acid (a polymer substantially composed of repeating units derived from a monomer selected from the group consisting of L-lactic acid and D-lactic acid)” and “a copolymer of L-lactic acid and/or D-lactic acid and a compound copolymerizable with L-lactic acid and/or D-lactic acid” may also be used.

In the present disclosure, the polymer containing polylactic acid is referred to as a “polylactic acid-based polymer”. In other words, the “polylactic acid-based polymer” means “polylactic acid (a polymer substantially composed of repeating units derived from a monomer selected from the group consisting of L-lactic acid and D-lactic acid)”, a “copolymer of L-lactic acid and/or D-lactic acid and a compound copolymerizable with L-lactic acid and/or D-lactic acid”, and mixtures thereof.

Among polylactic acid-based polymers, “polylactic acid” is particularly preferable, and it is most preferable to use a homopolymer of L-lactic acid (PLLA) and a homopolymer of D-lactic acid (PDLA).

The polylactic acid-based polymer may have a crystalline portion. Alternatively, at least a part of the polymer may be crystallized. As the polylactic acid-based polymer, it is preferable to use a polylactic acid-based polymer having piezoelectricity, in other words, a piezoelectric polylactic acid-based polymer, especially a piezoelectric polylactic acid.

Polylactic acid (PLA) is a chiral polymer, and a main chain thereof has a spiral structure. Polylactic acid can exhibit piezoelectricity when it is uniaxially stretched and molecules thereof are oriented. The piezoelectric constant may be increased by further performing heat treatment to increase the crystallinity. In other words, the “piezoelectric constant” can be increased according to the “crystallinity” (see “A Study of Mechanism of High Piezoelectric Performance Poly(lactic acid) Film Manufactured by Solid-State Extrusion”, Journal of the Institute of Electrostatics Japan, 40, 1 (2016) 38-43).

The piezoelectric constant of the polylactic acid (PLA) is, for example, 5 to 30 pC/N.

The optical purity (enantiomeric excess (e.e. %)) of polylactic acid (PLA) can be calculated by the following equation.

Optical purity (%)={|the amount of L-form−the amount of D-form|/(the amount of L-form+the amount of D-form)}×100

For example, with both of the D-form and the L-form, the optical purity is 90% by weight or more, preferably 95% by weight or more or 97% by weight or more, more preferably 98% by weight to 100% by weight, even more preferably 99.0% by weight to 100% by weight, and particularly preferably 99.0% by weight to 99.8% by weight. The amount of the L-isomer and the amount of the D-isomer of polylactic acid (PLA) may be, for example, values obtained by a method using high performance liquid chromatography (HPLC).

The crystallinity of polylactic acid (PLA) is, for example, 15% or more, preferably 35% or more, more preferably 50% or more, and still more preferably 55% to 100%. The crystallinity may be as high as possible, but may be, for example, 35% to 50%, and preferably 38% to 50% from the viewpoint of dyeability.

The crystallinity can be determined by a measurement method such as a method using a differential scanning calorimetry (DSC) (e.g., DSC 7000X manufactured by Hitachi High-Tech Science Corporation) and X-ray diffraction (XRD) (e.g., an X-ray diffraction method using ultraX 18 manufactured by Rigaku Corporation), wide angle X-ray diffraction (WAXD), or the like. In the present disclosure, it has been found that the measured value of the crystallinity measured using WAXD and the measured value of the crystallinity measured using DSC are different by about 1.5 times (DSC measured value/WAXD measured value≈1.5).

For the piezoelectric material of the present disclosure, besides the polylactic acid-based polymer, for example, optically active polymers, such as polypeptide-based polymers (e.g., poly(γ-benzyl glutarate) and poly(γ-methyl glutarate)), cellulose-based polymers (e.g., cellulose acetate and cyanoethylcellulose), polybutyric acid-based polymers (e.g., poly(β-hydroxybutyric acid)), and polypropylene oxide-based polymers, and derivatives thereof may be used as a polymeric piezoelectric substance.

The potential-generating fiber or potential-generating filament of the present disclosure is preferably free of additives such as plasticizers and/or lubricants. In general, it has been found that when an additive is contained in the potential-generating fiber or potential-generating filament, a surface potential tends to be hardly generated. Therefore, in order to appropriately generate the surface potential, it is preferable that the potential-generating fiber or potential-generating filament is free of additives. As used herein, the “plasticizer” is a material for imparting flexibility to the potential-generating fiber or potential-generating filament, and the “lubricant” is a material for improving molecular slippage of the piezoelectric yarn. Specifically, polyethylene glycol, castor oil-based fatty acid ester, polyoxyethylene sorbitan fatty acid ester, polyethylene glycol fatty acid ester, stearic acid amide and/or glycerin fatty acid ester and the like are contemplated. These materials are not contained in the potential-generating fiber or potential-generating filament of the present disclosure.

The potential-generating fiber or potential-generating filament of the present disclosure may contain a hydrolysis inhibitor. In particular, a hydrolysis inhibitor for polylactic acid (PLA) may be contained. As an example of the hydrolysis inhibitor, carbodiimide may be contained. More preferably, a cyclic carbodiimide may be contained. More specifically, the cyclic carbodiimide disclosed in Japanese Patent No. 5475377 may be used. By such a cyclic carbodiimide, the acidic group of a polymeric compound can be effectively sealed. Incidentally, a carboxyl group sealing agent may be used in combination with the cyclic carbodiimide compound to such an extent that the acidic group of the polymer can be effectively sealed. Examples of the carboxyl group sealing agent include agents disclosed in JP 2005-002174 A, for example, an epoxy compound, an oxazoline compound, and/or an oxazine compound.

Hereinafter, the role of the hydrolysis inhibitor will be described. A hitherto commonly known fiber or filament containing PLA (a fiber or filament that does not generate a surface potential) generates an acid through hydrolysis of PLA, and the acid acts on bacteria to exhibit an antibacterial effect. Therefore, when hydrolysis occurs in the PLA, the fiber or filament is deteriorated. However, since the potential-generating fiber or potential-generating filament of the present disclosure has an antibacterial mechanism different from the conventional one and exhibits an antibacterial effect by generating a surface potential as described above, it is not necessary to cause hydrolysis. Furthermore, since the potential-generating fiber or potential-generating filament of the present disclosure contains a hydrolysis inhibitor, it is possible to prevent hydrolysis from occurring in the fiber or filament and to inhibit deterioration of the fiber or filament.

The fiber of the present disclosure may be a yarn obtained by aligning a plurality of fibers (a paralleled yarn or a non-twisted yarn), may be a twisted yarn (a stranded yarn or a twisted yarn), may be a crimped yarn (a crimped yarn or a false twisted yarn), or may be a spun yarn (a spun yarn). In other words, the present disclosure may be a yarn containing the modified cross-section fiber of the present disclosure (hereinafter, the yarn may also be referred to as “yarn of the present disclosure” or “antibacterial yarn”).

The modified cross-section fiber of the present disclosure and/or the yarn comprising the modified cross-section fiber of the present disclosure may be contained in a cloth. In other words, the present disclosure may be a cloth comprising the modified cross-section fiber of the present disclosure and/or the yarn comprising the modified cross-section fiber of the present disclosure. In the present disclosure, the “cloth” means a fabric such as a woven fabric, a knitted fabric, or a nonwoven fabric.

The modified cross-section fiber of the present disclosure will be described in detail in the following Examples.

### EXAMPLES

### Example 1

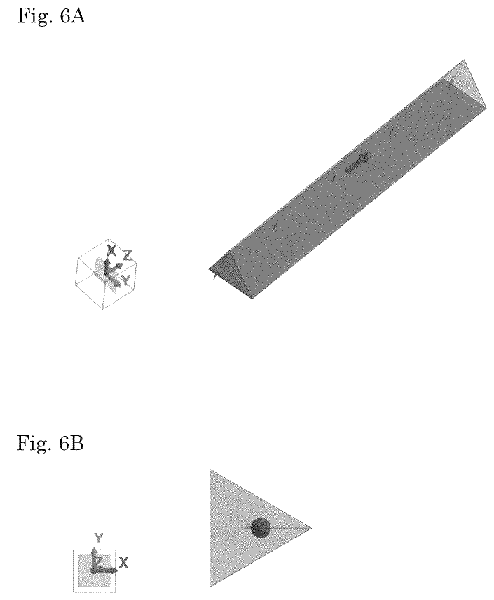

Using simulation software “FEMTET” (https://www.muratasoftware.com/) produced by Murata Software Co., Ltd., the potential (mV) and the electric field intensity (kV/m) of the modified cross-section fiber of the present disclosure having a triangular fiber cross section illustrated in FIGS. 6A and 6B were measured under the following conditions.

Model
Triangular prism
Fiber cross section: equilateral triangle
Interior angle: 60°
Length (dimension in Z-axis direction): 100 μm
Height (height in X-axis direction) (distance from YZ plane to vertex): 10 μm
Load: 2×10′N
Material: poly-L-lactic acid (PLLA) film (tensor components of piezoelectric (strain) constant: d¹⁴=6 pC/N, d₂₅=−6 pC/N)

A load is applied in a direction of 45° with respect to the YZ plane in the perspective view of FIG. 6A (in other words, a direction inclined by 45° from a direction perpendicular to the longitudinal axis of the fiber).

FIG. 6B illustrates a section (section on the XY plane) of the fiber illustrated in FIG. 6A, and shows that a load is applied from a vertex toward the inside of a triangle or in a central direction.

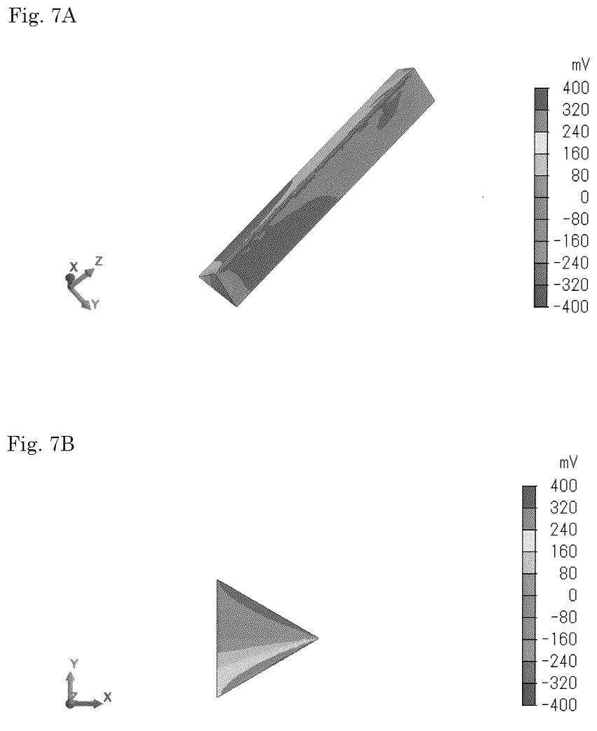

The potential (mV) generated in the fiber when a load (2×10⁻⁴ N) is applied to the modified cross-section fiber illustrated in FIGS. 6A and 6B is shown in FIGS. 7A and 7B.

FIG. 7A shows the potential generated in the entire fiber, and FIG. 7(B) shows the potential generated in the cross section of the fiber.

In FIGS. 7A and 7B, the maximum value of the generated potential was 371.591 mV, and the minimum value of the generated potential was −359.408 mV.

As shown in FIG. 7B, it was found that the potential was significantly higher on the side surfaces located on both sides of a vertex of the fiber than on the vertex of the fiber to which the load was applied.

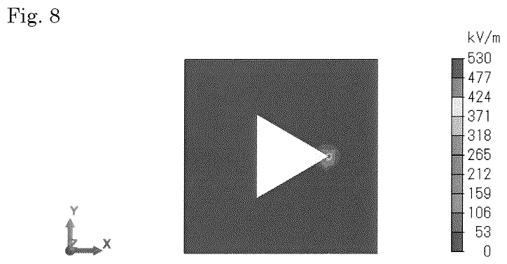

The intensity of the electric field generated when a load (2×10⁻⁴ N) was applied to the modified cross-section fiber is shown in FIG. 8. FIG. 8 shows a section (section on the XY plane) of the fiber, and shows the intensity (kV/m) of the electric field generated in the fiber.

As shown in FIG. 8, it was found that the electric field intensity was remarkably high at the vertex of the fiber to which the load was applied.

The maximum value of the electric field intensity was 527 kV/m (see FIG. 9).

### Example 2

The electric field intensity was determined in the same manner as in Example 1 except that a quadrangular prism (fiber cross section: square, interior angle: 90°) was used as a model. The maximum value of the electric field intensity was 202 kV/m (see FIG. 9).

### Example 3

The electric field intensity was determined in the same manner as in Example 1 except that a pentagonal prism (fiber cross section: regular pentagon, interior angle: 108°) was used as a model. The maximum value of the electric field intensity was 152 kV/m (see FIG. 9).

### Comparative Example 1

The electric field intensity was determined in the same manner as in Example 1 except that a hexagonal prism (fiber cross section: regular hexagon, interior angle: 120°) was used as a model. The maximum value of the electric field intensity was 36 kV/m (see FIG. 9).

### Comparative Example 2

The electric field intensity was determined in the same manner as in Example 1 except that a heptagonal prism (fiber cross section: regular heptagon, interior angle: 128.57°) was used as a model. The maximum value of the electric field intensity was 32 kV/m (see FIG. 9).

### Comparative Example 3

The electric field intensity was determined in the same manner as in Example 1 except that an octagonal prism (fiber cross section: regular octagon, interior angle: 135°) was used as a model. The maximum value of the electric field intensity was 50 kV/m (see FIG. 9).

### Comparative Example 4

The electric field intensity was determined in the same manner as in Example 1 except that a decagonal prism (fiber cross section: regular decagon, interior angle: 144°) was used as a model. The maximum value of the electric field intensity was 56 kV/m (see FIG. 9).

### Comparative Example 5

The electric field intensity was determined in the same manner as in Example 1 except that a dodecagonal prism (fiber cross section: regular dodecagon, interior angle: 150°) was used as a model. The maximum value of the electric field intensity was 58 kV/m (see FIG. 9).

### Comparative Example 6

The electric field intensity was determined in the same manner as in Example 1 except that a tetradecagonal prism (fiber cross section: regular tetradecagon, interior angle: 154.285°) was used as a model. The maximum value of the electric field intensity was 75 kV/m (see FIG. 9).

### Comparative Example 7

The electric field intensity was determined in the same manner as in Example 1 except that a hexadecagonal prism (fiber cross section: regular hexadecagon, interior angle: 157.5°) was used as a model. The maximum value of the electric field intensity was 79 kV/m (see FIG. 9).

As shown in the graph of FIG. 9, it was found that when the angle measure of an interior angle of the modified cross-section fiber was 120° or more as in Comparative Examples 1 to 7, the electric field intensity was significantly reduced. In Comparative Example 1 to 7, it was found that the electric field intensity was less than 100 kV/m or less than 0.1 V/μm.

On the other hand, in Examples 1 to 3, since the angle measure of an interior angle of the modified cross-section fiber was less than 120°, it was found that the electric field intensity was 100 kV/m or more or 0.1 V/μm or more.

From the fact that such an electric field intensity is obtained, it was found that each of the modified cross-section fibers of Examples 1 to 3 exhibits a significantly improved electric field intensity (0.1 V/μm or more) when receiving a compressive force from a direction oblique with respect to the longitudinal axis direction of the fiber, particularly, in a direction oblique by 45°.

### Example 4

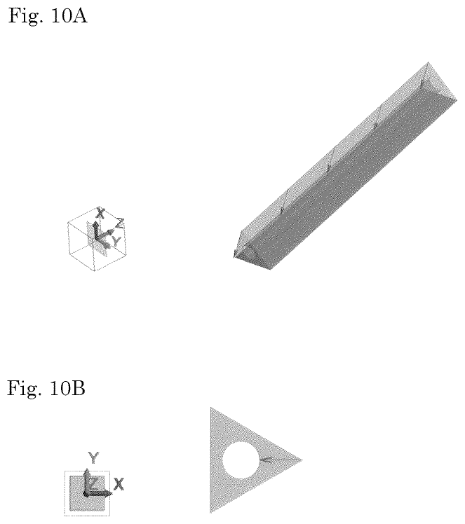

Using simulation software “FEMTET” (produced by Murata Software Co., Ltd.), the potential (mV) and the electric field intensity (kV/m) of a “hollow” modified cross-section fiber of the present disclosure having a triangular fiber cross-section shown in FIGS. 10A and 10B were measured under the following conditions.

Model
Triangular prism (hollow)
Fiber cross section: equilateral triangle
Interior angle: 60°
Length (dimension in Z-axis direction): 100 μm
Height (height in X-axis direction) (distance from YZ plane to vertex): 10 μm
Hollow (cylindrical hollow portion): Radius of hollow portion (hereinafter referred to as “hollow radius”): 3 μm, dimension in Z-axis direction: 100 μm
Load: 2×10⁻⁴ N
Material: poly-L-lactic acid (PLLA) film (tensor components of piezoelectric (strain) constant: d₁₄=6 pC/N, d₂₅=−6 pC/N)

A load is applied in a direction of 45° with respect to the YZ plane in the perspective view of FIG. 10A (in other words, a direction inclined by 45° from a direction perpendicular to the longitudinal axis of the fiber).

FIG. 10B illustrates a section (section on the XY plane) of the fiber illustrated in FIG. 10A, and shows that a load is applied in a direction directed from a vertex toward the central of a triangle.

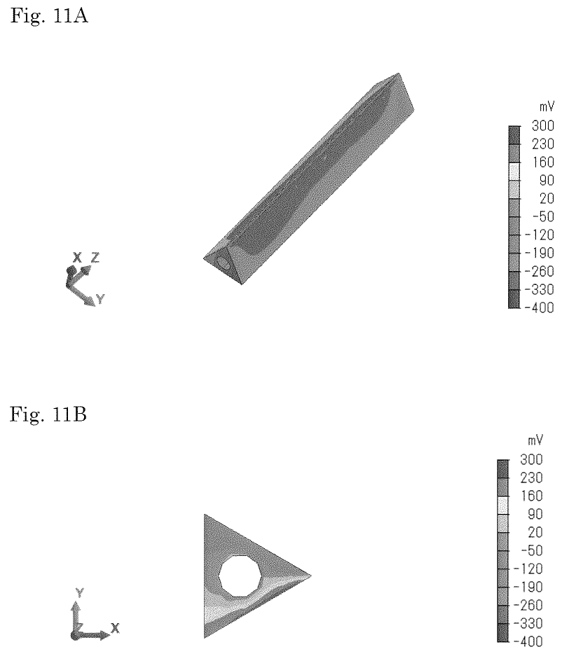

The potential (mV) generated in the fiber when a load (2×10⁻⁴ N) is applied to the modified cross-section fiber illustrated in FIGS. 10A and 10B is shown in FIGS. 11A and 11B.

FIG. 11A shows the potential generated in the entire fiber, and FIG. 11B shows the potential generated in the cross section of the fiber.

In FIGS. 11A and 11B, the maximum value of the generated potential was 281 mV, and the minimum value of the generated potential was −343 mV.

As shown in FIG. 11B, it was found that the potential was significantly higher on the side surfaces located on both sides of a vertex of the fiber than on the vertex of the fiber to which the load was applied.

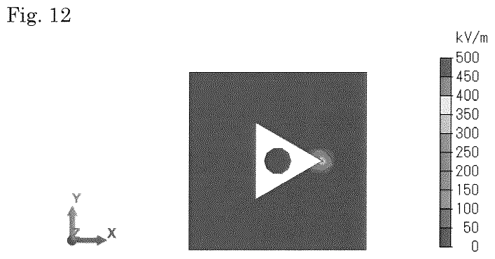

The intensity of the electric field generated when a load (2×10⁻⁴ N) was applied to the modified cross-section fiber is shown in FIG. 12. FIG. 12 shows a section (section on the XY plane) of the fiber, and shows the intensity (kV/m) of the electric field generated in the fiber.

As shown in FIG. 12, it was found that the electric field intensity was remarkably high at the vertex of the fiber to which the load was applied.

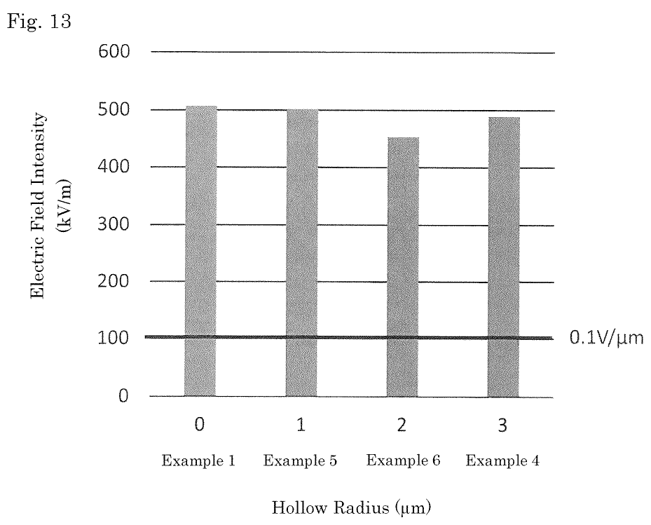

The maximum value of the electric field intensity was 489 kV/m (see FIG. 13).

In FIG. 13, the case where the radius (hollow radius) is 0 μm indicates the electric field intensity of the fiber (solid) of Example 1.

### Example 5

The electric field intensity was determined in the same manner as in Example 4 except that the hollow radius was set to 1 μm. The maximum value of the electric field intensity was 502 kV/m (see FIG. 13).

### Example 6

The electric field intensity was determined in the same manner as in Example 4 except that the hollow radius was set to 2 μm. The maximum value of the electric field intensity was 453 kV/m (see FIG. 13).

As shown in the graph of FIG. 13, in Examples 4 to 6, it was found that even the hollow fibers had an electric field intensity of 100 kV/m or more or 0.1 V/μm or more.

From the fact that such an electric field intensity can be obtained, it was found that even though each of the modified cross-section fibers of Examples 4 to 6 was a hollow fiber, it exhibited a significantly improved electric field intensity (0.1 V/μm or more) when receiving a compressive force from a direction oblique with respect to the longitudinal axis direction of the fiber.

### Example 7

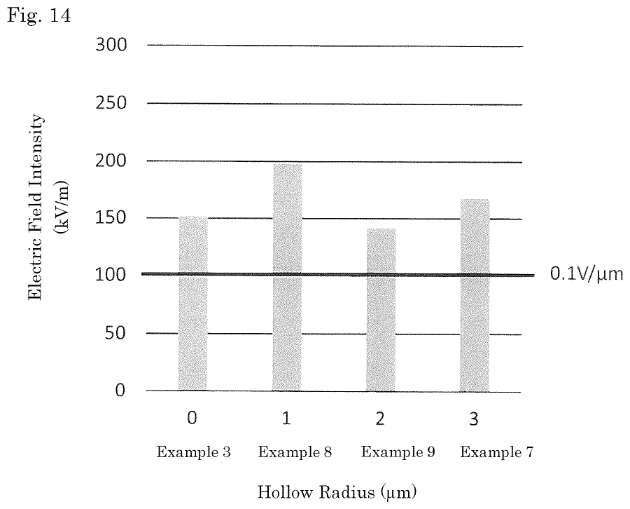

The electric field intensity was measured in the same manner as in Example 4 except that the “hollow” modified cross-section fiber (hollow radius: 3 μm, dimension in Z-axis direction: 100 μm) of the present disclosure having a regular pentagonal fiber cross-section was used. The maximum value of the electric field intensity was 168 kV/m (see FIG. 14). In FIG. 14, the case where the radius (hollow radius) is 0 μm indicates the electric field intensity of the fiber (solid) of Example 3.

### Example 8

The electric field intensity was determined in the same manner as in Example 7 except that the hollow radius was set to 1 μm. The maximum value of the electric field intensity was 198 kV/m (see FIG. 14).

### Example 9

The electric field intensity was determined in the same manner as in Example 7 except that the hollow radius was set to 2 μm. The maximum value of the electric field intensity was 142 kV/m (see FIG. 14).

As shown in the graph of FIG. 14, in Examples 7 to 9, it was found that even the hollow fibers had an electric field intensity of 100 kV/m or more or 0.1 V/μm or more.

From the fact that such an electric field intensity can be obtained, it was found that even though each of the modified cross-section fibers of Examples 7 to 9 was a hollow fiber, it exhibited a significantly improved electric field intensity (0.1 V/μm or more) when receiving a compressive force from a direction oblique with respect to the longitudinal axis direction of the fiber.

Reliability of Simulation Software

In order to confirm the reliability of the simulation software “FEMTET” ((https://www.muratasoftware.com/) produced by Murata Software Co., Ltd.) used in the above Examples and Comparative Examples, the following experiments were carried out.

(Confirmation Experiment)

(1)

Piezoelectric simulation was carried out with a PLLA film (dimension in longitudinal direction: 40 mm, dimension in direction perpendicular to longitudinal direction: 20 mm, depth: 0.05 mm) using simulation software “FEMTET”.

Conditions
Solver: piezoelectric analysis
Boundary conditions: 0.5% tension

The potential generated in the poly-L-lactic acid (PLLA) film (tensor components of piezoelectric (strain) constant: d₁₄=6 pC/N, d₂₅=−6 pC/N) was 71.5 V.

(2)

Using a PLLA film (dimension in longitudinal direction: 40 mm, dimension in direction perpendicular to longitudinal direction: 20 mm, depth: 0.05 mm) (PLLA: poly-L-lactic acid (PLLA) having an optical purity of 99% or more, a crystallinity of 44%, a crystal size of 13.5 nm, an orientation of 90%, and a tensor components of a piezoelectric (strain) constant of d₁₄=6 pC/N and d₂₅=−6 pC/N), the potential generated at 0.5% tension was actually measured under the following conditions.

Conditions
Tension: 0.5% (longitudinal direction)
Potential measurement: electric force microscope (EFM)

A probe of an electric force microscope (EFM) (Model 1100TN manufactured by TREK, Inc.) was fixed to a cantilever, and the probe was scanned 200 μm in the longitudinal direction of the PLLA film to measure a potential of the PLLA film at 0.5% tension. At this time, a ground (GND) was formed in a tensile device (jig) from the PLLA film via the jig, and the PLLA film was blown with an ionizer (MODEL 930 manufactured by TREK, Inc.) for 1 minute to stabilize a measured value.

The potential of the PLLA film at 0.5% tension was 71.1 V to 72.1 V, which was almost the same as the above-described result (71.5 V) measured using simulation software “FEMTET” manufactured by Murata Software Co., Ltd.

(Relationship Among Tension, Compression, and Electric Field Intensity in Simulation)

The electric field intensity E can be determined from the following equation.

D=dT+ε^{T}E
D: electrical displacement
d: piezoelectric constant
T: stress
ε^{T}: dielectric constant
E: electric field intensity

When the simulation software “FEMTET” is used, the “electric field intensity E” can be determined from “d (piezoelectric constant)”, “T (stress)”, and “ε^{T} (dielectric constant)” because D (electrical displacement)=0 in the simulation of a modified cross-section fiber. Here, since “d (piezoelectric constant)” and “ε^{T} (dielectric constant)” are constant values, “electric field intensity E” mainly depends on “T (stress)”. Here, the magnitude (value) of “T (stress)” is important, and as can be seen from the above equation, the direction of the stress is not involved in “electric field intensity E” at all. Therefore, with respect to the “electric field intensity E”, if the magnitudes of the “tension” in the longitudinal direction of the film and the “compression” crossing the longitudinal direction of the fiber are the same, the value of the “electric field intensity E” is the same.

In addition, from the following equation, there is the following correlation between the “electric field intensity E” and the “potential V”.

E=V/α
V: potential
α: distance

From the above, when the result of the “potential” (V) or the “electric field intensity” (E) derived from the “tension” by the simulation software “FEMTET” and the result of the “potential” or the “electric field intensity” actually measured from the “tension” coincide with each other (see the “confirmation experiment” described above), it can be said that the results of the “potential” and the “electric field intensity” obtained from the “compression” by the simulation software “FEMTET” are theoretically the same as the actually measured values.

As described above, the simulation software “FEMTET” produced by Murata Software Co., Ltd. has certain reliability.

Antibacterial Effect

As to the antibacterial effect, briefly explaining a germ to be taken as a target, bacteria and fungi, particularly fungi, are composed of elongated hyphae and spores having a basically circular shape. In addition, it is known that spores proliferate by germination, and when they float in the air or the like and adhere to parasites, they form hyphae and reproduce both sexually and asexually (“Textbook of Modern Dermatology”, 2nd edition, written by Hiroshi SHIMIZU, page 469). The size of spores that contribute to such proliferation is generally about 2 μm to about 10 μm (“Window of Food Sanitation”, the website of Bureau of Social Welfare and Public Health, Tokyo Metropolitan Government).

Next, briefly explaining the antibacterial effect by electrical stimulation, it has been conventionally known that proliferation of germs can be suppressed by an electric field (see, for example, Tetsuaki Tsuchido, Hiroki Kourai, Hideaki Matsuoka, and Junichi Koizumi “Microbial Control-Science and Engineering”: Kodansha; and see for example, Koichi Takaki “Agricultural and Food Processing Applications of High-Voltage and Plasma Technologies,” J. HTSJ, Vol. 51, No. 216).

In addition, it has also been found that: by virtue of a potential that generates such an electric field, a current may flow through a current path formed by moisture or the like or a circuit that can be formed by a local micro discharge phenomenon or the like, and germs are weakened by such an electric current and the proliferation of germs can be suppressed.

Furthermore, in relation to such electrical stimulation, an electroporation method has been known as one of the mechanisms of cell membrane destruction (Mechanism of electroporation: Basis of electric-pulse mediated gene transfer, written by Michio KASAI and Hiroko INABA, page 1595).

According to the above document, the condition under which electroporation that destroys cell membranes of germs and the like occurs is generally that a potential difference (or voltage) of “about 1.0 V” is applied to cells, and the present inventors have considered that, for example, in a case where the size of a spore is about 2 μm to about 10 μm, when an electric field or potential having an electric field intensity of about 0.1 V/μm or more is generated, a potential difference (or voltage) of about 1.0 V or more can be applied even in the case of a spore having a size of about 10 μm at the maximum, so that cell membranes may be destroyed due to the occurrence of electroporation, or an electron transfer system for life support may be hindered, leading to weakening, killing, or reduction of cells.

Therefore, the modified cross-section fibers of the present disclosure of Examples 1 to 9 have an electric field intensity of 0.1 V/μm or more, and thus exhibit a superior antibacterial effect. In addition, it is considered that the modified cross-section fibers can also act on viruses due to such an electric field intensity of 0.1 V/μm or more.

The modified cross-section fibers of the present disclosure should not be construed as limited to the above examples.

The modified cross-section fiber of the present disclosure can be used, for example, in clothing, particularly in socks and the like. The modified cross-section fiber of the present disclosure is not limited to clothing and can be used in various fabrics and/or yarns to which a compressive force is applied. For example, it can be used in insoles of shoes, rugs such as carpets, floor materials, and the like.

What is claimed is:

1. A fiber comprising a potential generating filament having at least one interior angle of less than 120° in a contour shape in a sectional view in a direction perpendicular to a longitudinal axis of the fiber.

2. The fiber according to claim 1, wherein the angle measure of the interior angle is 108° or less.

3. The fiber according to claim 1, wherein the interior angle is 90° or less.

4. The fiber according to claim 1, wherein the interior angle is 60° or less.

5. The fiber according to claim 1, wherein the interior angle is 60° to 108°.

6. The fiber according to claim 1, wherein the fiber is constructed such that a potential is generated when the fiber is pressed in a direction transverse to the longitudinal axis of the fiber.

7. The fiber according to claim 6, wherein the potential is generated by pressing a corner included in the contour shape of the fiber.

8. The fiber according to claim 7, wherein the potential is generated by pressing the corner obliquely from a direction perpendicular to the longitudinal axis of the fiber.

9. The fiber according to claim 8, wherein the potential is generated by pressing the corner obliquely in a range of 0° to 90° from the direction perpendicular to the longitudinal axis of the fiber.

10. The fiber according to claim 9, wherein the potential is generated by pressing the corner obliquely at 45° from a direction perpendicular to the longitudinal axis of the fiber.

11. The fiber according to claim 1, wherein the fiber is a hollow fiber.

12. The fiber according to claim 1, wherein the fiber has an electric field intensity of 100 kV/m or more or 0.1 V/μm or more.

13. The fiber according to claim 1, wherein the fiber contains a piezoelectric material.

14. The fiber according to claim 13, wherein the piezoelectric material comprises poly-L-lactic acid.

15. The fiber according to claim 13, wherein the piezoelectric material is free of additives.

16. The fiber according to claim 13, wherein the piezoelectric material comprises a hydrolysis inhibitor.

17. The fiber according to claim 1, wherein the contour shape of the fiber is triangular, quadrangular, pentagonal, or hexagonal.

18. The fiber according to claim 17, wherein all vertices of the contour shape are inscribed in a circle.

19. A yarn comprising the fiber according to claim 1.

20. A cloth comprising the yarn according to claim 19.
